(19) United States
(12) Patent Application Publication
(10) Pub. No.: US 2024/0023443 A1
(43) Pub. Date: Jan. 18, 2024

(54) HEAT EXCHANGER ENHANCED WITH THERMOELECTRIC GENERATORS

(71) Applicant: B aryon Inc., Wilmington, DE (US)

(72) Inventors: Demis Lukasz Pandelidis, Wroclaw (PL); Korneliusz Sierpowski, Wroclaw (PL); Jeffrey Premer, Las Vegas, NV (US)

(21) Appl. No.: 18/198,960

(22) Filed: May 18, 2023

Related U.S. Application Data
(60) Provisional application No. 63/390,095, filed on Jul. 18, 2022.

(51) Int. Cl. H10N 10/17

(52) U.S. Cl. CPC H10N 10/17

(57) ABSTRACT

The present disclosure relates to an evaporative heat exchanger enhanced with thermoelectric generators which allow for the collection of electrical energy during heat transfer process. The present disclosure consists of a heat exchanger.

### CROSS-REFERENCE TO OTHER APPLICATION

This application claims the benefit of and priority to U.S. Provisional Application No. 63/390,095 filed Jul. 18, 2022, the contents of which is hereby incorporated by reference.

### GOVERNMENT FUNDING

This invention was made with Government support under DE-EE0009683 awarded by the United States Department of Energy. The Government has certain rights in this invention.

### FIELD OF THE DISCLOSURE

The present disclosure relates to a heat exchanger that collects electrical energy during the heat transfer process and uses the energy to power other components of the heat exchanger.

### BACKGROUND OF THE DISCLOSURE

Thermoelectric generators, also known as “Seebeck generators” are devices which convert thermal energy (i.e., temperature differences) into electrical energy. Specifically, Thermoelectric generators generate power directly from heat by converting temperature differences into electric voltage. This electrical energy can be converted into additional electrical power such as is used in power plants and in automobiles.

The general operation of and uses for a heat exchanger are commonly known in the art. Specifically, heat exchangers may be used as part of air conditioning systems as disclosed in U.S. patent application Ser. No. 17/987,063, which is incorporated by reference. However, heat exchangers generate and produce a significant amount of waste heat due to the high temperature differences present throughout heat exchangers. This wasted heat could instead be converted into additional electrical power to create a more efficient heat exchange process. This disclosure improves upon the prior art by incorporating Thermoelectric generators (“TEG”) into the structure of a heat exchanger.

Historically, TEGs have not been incorporated into heat exchangers due to TEGs having a low heat to electricity conversion efficiency. Additionally, TEGs have been prohibitively expensive considering their low efficiency and lower cost version of TEGs are even less efficient at converting heat flux to electrical current. However, in the case of evaporative heat exchangers, the heat flux is significant due to the high value of latent heat evaporation. Therefore, if the heat transfer surfaces in the heat exchangers incorporate TEGs, the TEGs can generate enough electricity to power supplemental equipment, such as fans to push air through the exchanger, or pumps which deliver water for evaporation. In other words, the scale of heat flux compensates for the low efficiency of the TEGs and allows the TEGs to power supplemental equipment without the need for external energy. Additionally, systems which use evaporative heat exchangers tend to consume less energy. Therefore systems which incorporate evaporative heat exchangers and TEGs can more easily meet energy requirements in comparison to traditional systems which use heat exchangers.

Thus, there exists a long-felt and currently unmet need for a system which allows for a more efficient heat exchanger by use of Thermoelectric generators.

### SUMMARY OF THE DISCLOSURE

The present disclosure consists of a heat exchanger with a thermoelectric generator located on or between the channel walls/plates. Heat-transferring airflows pass through the channels and transfer heat from one channel to the next. The transferring heat passes through the exchanger walls and consequently through the thermoelectric generator where part of it is converted to electrical energy. The obtained electrical energy is then used to power the supplementary equipment required by the heat exchanger or for use in other applications.

### BRIEF DESCRIPTION OF THE DRAWINGS

The following detailed description, given by way of example, but not intended to limit the disclosure solely to the specific embodiments described, may best be understood in conjunction with the accompanying drawings.

FIG. 1 shows a scheme for a heat exchanger wherein thermoelectric generators are placed between the channel walls of the heat exchanger.

FIG. 2 shows a system for the heat exchanger of FIG. 1 wherein thermoelectric generators are placed between an alternating series of wet and dry channel walls.

FIG. 3 displays an alternative embodiment of the system of FIG. 2 wherein the thermoelectric generators are placed on the dry side of the channel walls.

FIG. 4 displays an alternative embodiment of the system of FIG. 2 wherein the thermoelectric generators are the channel walls.

FIG. 5 displays an alternative embodiment of the system of FIG. 2 wherein the thermoelectric generators are embedded into the channel walls.

### DETAILED DESCRIPTION OF THE DISCLOSURE

For the purposes of promoting and understanding the principles disclosed herein, reference is now made to the preferred embodiments illustrated in the drawings, and specific language is used to describe the same. It is nevertheless understood that no limitation of the scope of the invention is hereby intended. Such alterations and further modifications in the illustrated devices and such further applications of the principles disclosed and illustrated herein are contemplated as would normally occur to one of skill in the art to which this disclosure relates.

The inventors of the present disclosure have created a new apparatus 100, 200, 300, 400 to increase the efficiency of a heat exchanger 102, 202, 302, 402. In the present disclosure, the heat exchanger 102, 202, 302, 402 is equipped with a thermoelectric generator (TEG) 116, 216, 316, 416. The heat exchanger 102, 202, 302, 402 comprises a series of dry channels 104, 204, 304, 404 and wet channels 106, 206, 306, 406. The present disclosure may be used in any type of heat exchanger 102, 202, 302, 402 including but not limited to a plate heat exchanger, a shell-tube heat exchanger, or any other type of heat exchanger which allows for evaporative heat exchange. In addition, the heat exchanger may contain two or media exchanging heat (i.e., a two-flow or multi-flow unit). As shown, the heat exchanger 102, 202, 302, 402 cycles a first heat transferring fluid 112, 212, 312, 412 and a second heat transferring fluid 114, 214, 314, 414.

In alternative embodiments, the heat transferring fluids comprise air, water, glycol, or any other liquids or gasses capable of heat exchange.

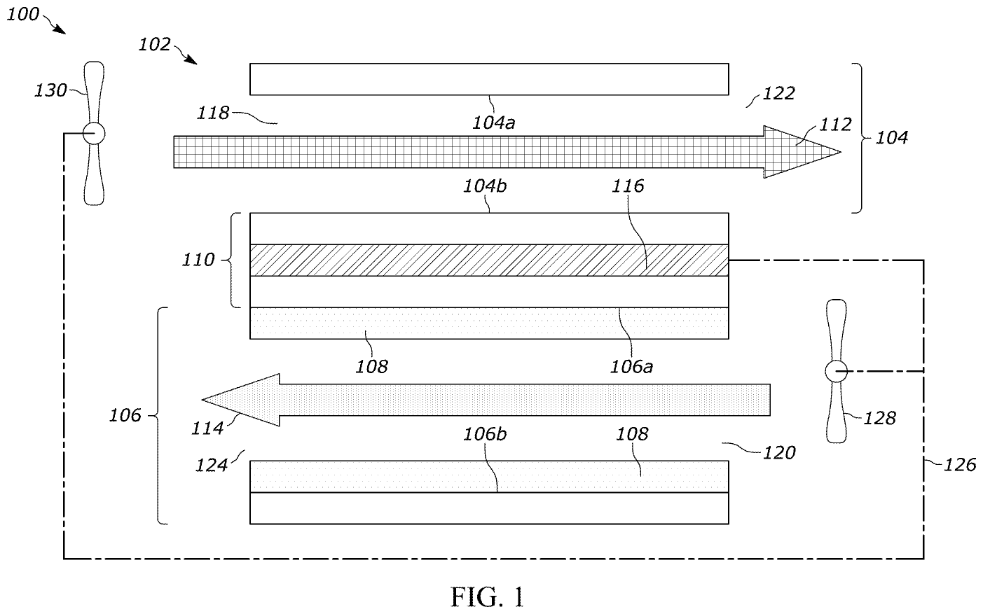

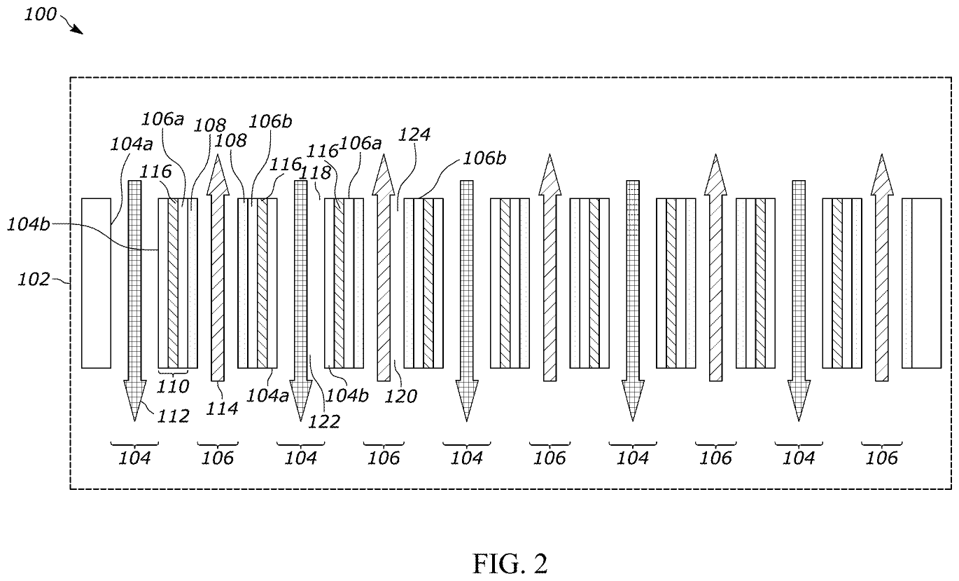

FIGS. 1 and 2 depict a heat exchanger comprising a dry channel 104 and a wet channel 106. The walls of the dry channel 104a, 104b and the walls of the wet channel 106a, 106b are thermally coupled, such that a change in temperature of the wet channel wall 104b results in a corresponding change of temperature of the thermally coupled dry channel wall 106a. In the embodiment shown, the walls of the wet 106a and dry working channels 104b are coupled to form a shared wall/plate 110 made from a thermally conductive material. As shown in the embodiment of FIG. 1, the TEGs 116 are located between the dry 104b and wet channel 106a walls to form the corresponding plate 110. Each channel 104, 106 forms an enclosed space passing from a respective fluid inlet 118, 120 to a fluid outlet 122, 124. Fluid flows from each inlet, through the respective channel, to the outlet. The walls 106a, 106b of the wet channel are coated in a liquid 108. In the embodiment shown, the walls 106a, 106b are coated in water 108. As the second heat transferring fluid 114 passes through the wet channel 106, water from the walls 106a, 106b evaporates, thereby reducing the temperature of the walls 106a, 106b. As the walls of the wet channel 106 cool, heat is transferred from the dry channel 104 to the wet channel 106. The first heat transferring fluid passing through the dry channel 104 is thereby cooled through contact with the dry channel walls 104a, 104b.

The volume of heat transferring media can be increased if the heat exchanger is a multi-flow unit. The heat flux passes through the heat exchanger walls and consequently through the TEG and/or TEGs 116 and the heat flux (i.e., the change in heat) is converted to electrical energy.

In the embodiment shown in FIG. 1, the TEGs 116 are located between every channel wall of the heat exchanger and extend the length of the entirety of the channel wall. In an alternative embodiment, the TEGs 116 are located between at least one channel wall and extend the length of at least a portion of the channel wall.

In the embodiment shown in FIG. 1, the heat exchanger 102, plates 110, and TEGs 116 are comprised of a non-woven fabric, such as a Polyethylene Terephthalate (PET) non-woven fabric. In other embodiments, the plates/walls 110, and TEGs 116 are comprised of materials suitable for heat exchange which include but are not limited to metals and metal alloys, such as aluminum, copper, carbon steel, stainless steel, nickel alloys, and titanium. In another embodiment, the plates/walls 110 and TEGs 116 are comprised of ceramic material.

In the embodiment shown in FIG. 1, the heat transfer process is continuous, allowing the TEGs 116 to continuously generate electrical energy and enhance the performance of the unit. The collected electrical energy can be used to power the supplementary equipment required by the heat exchanger 102 (e.g., pumps or fans), or it can be used for other applications. In an embodiment, the TEGs 116 are connected to an electrical wire 126 which are connected to a dry channel fan 130 and a wet channel fan 128. The dry channel fan 130 moves the first heat transferring fluid 112 through the dry channel 104 and the wet channel fan 128 moves the second heat transferring fluid 114 through the wet channel 106. The TEGs 116 power the fans 128,130 through the conversion of the heat flux between the channels 104,106 into electrical energy. Alternatively, the fans 128, 130 may be replaced with pumps to deliver water for evaporation.

As shown in FIG. 2, the heat exchanger 102 comprises multiple dry channels 104 and multiple wet channels 106 which are thermally coupled together in an alternating series. In embodiments, each dry channel 104 is thermally coupled to a single wet channel 106. In alternative embodiments, multiple dry channels 104 are thermally coupled to one or more wet channels 106.

In an embodiment, either a wet or dry channel wall 104a, 104b, 106a, 106b may form the ends of the heat exchanger. Alternatively, a channel plate 110 may act as the wall of the heat exchanger 102 and serve to thermally couple the dry and wet channels 104, 106 together. In other embodiments, the channels 104, 106 are set in alternative arrangements that permit heat transfer between the channels.

Although the foregoing discussion refers to the dry channel 104 and wet channel 106 as having “walls” 104a, 104b, 106a, 106b, it will be understood that any three-dimensional arrangement could be used. In an embodiment, the channels 104, 106 each comprise a cylinder. Substantially all of the walling of the wet channel 106 may be coated in water. Alternatively, the channels 104, 106 may comprise rectangular prisms. In such embodiment, only the “floor” of the wet channel may be coated in water 108. As will be clear to one of skill in the art, the cooling capacity of the system 100 may be selected by adjusting the number of channels 104, 106 and/or the area of contact between the walls 110 of the channels 104, 106 and the fluid 112, 114 passing through the channels 104, 106. Greater contact area will increase the amount of evaporation and/or condensation, thereby enabling both the degree of pre-cooling and the amount of dehumidification to be adjusted based on the desired capacity of the system 100.

As the second heat transferring fluid 114 passes through the wet working channel 106, the fluid 114 absorbs the liquid 108 on the channel walls 106a, 106b. The absorption of liquid 108 removes heat from the wet channel walls 106a, 106b and cools the shared plate 110. In turn, the shared plate 110 cools the dry working channel 104 as well as the first heat transferring fluid 112 passing through the dry working channel 104.

In an embodiment, a fluid connection between the dry channel 104 and the wet channel 106 continuously replenishes the supply of liquid 108 in the wet channel 106 with moisture from the dry channel 104. In an embodiment, the fluid 108 connection is entirely passive, such that no external energy is needed to transport moisture from the dry channel 104 to the wet channel 106. In an embodiment, the dry channel 104 is located higher than the wet channel 106 such that gravity effectuates the transfer of moisture from the dry channel 104 to the wet channel 106. In an embodiment, the fluid connection is structured such that capillary action effectuates the transfer of moisture from the dry channel 104 to the wet channel 106. In an embodiment, the walls 104a, 104b of the dry channel are coated with a hydrophobic substance, such that water collecting thereon is driven through the fluid connection to the wet channel 106. As will be clear to one of skill in the art, combinations of these embodiments and other passive transport techniques may be used to effectuate the transfer of moisture from the dry channel 104 to the wet channel 106 while preventing backflow of moisture from the wet channel 106 to the dry channel 104.

In embodiments, an active source is used to effectuate the transfer of moisture from the dry channel 104 to the wet channel 106. In an embodiment, a pump is used. In an alternative embodiment, active and passive mechanisms are combined to ensure continuous and efficient movement of water from the dry channel 104 to the wet channel 106.

In an embodiment, an external source is used to replenish the water 108 in the wet channel 106. The external source may comprise a connection to a local water supply and/or distilled water that is obtained from a reservoir.

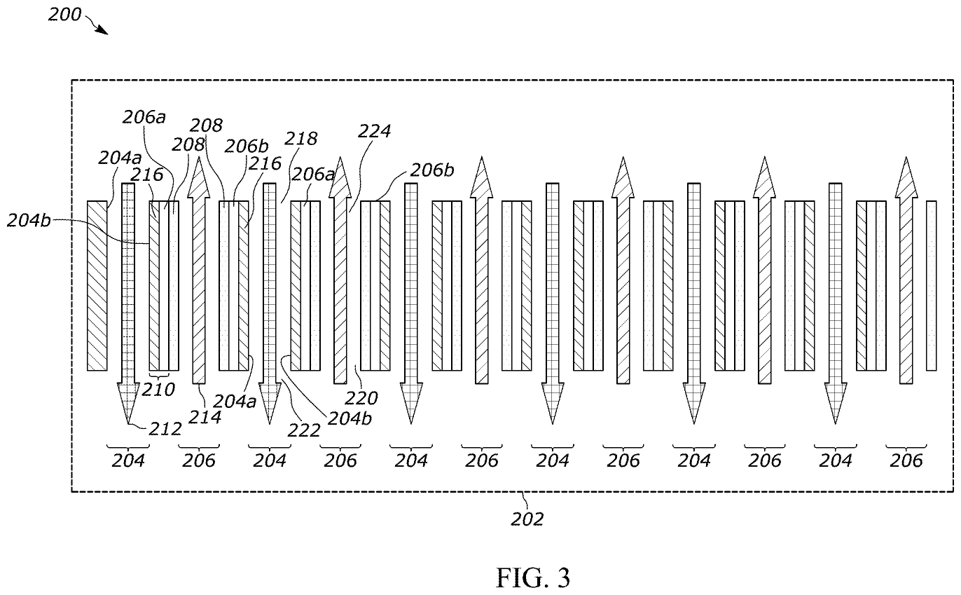

FIG. 3 shows a heat exchanger 202 wherein TEGs 216 are located on one side of the channel plate 210 and form the wall of one of the dry or wet channels. In the embodiment of FIG. 3, similarly labeled elements are incorporated into this embodiment 200 (i.e., elements 102 and 202 both represent the heat exchanger).

FIG. 3 shows the heat exchanger 202 comprising an alternating series of dry channels 204 and wet channels 206 thermally coupled together. In embodiments, each dry channel 204 is thermally coupled to a single wet channel 206. In alternative embodiments, multiple dry channels 204 are thermally coupled to one or more wet channels 206. As shown in the embodiment of FIG. 3, the TEGs 216 form the walls of the dry channel 204 and are thermally coupled to the wet channel walls 206a to form the corresponding plate 210.

In an embodiment, either a wet or dry channel wall 204a, 204b, 206a, 206b may form the ends of the heat exchanger 202. In an alternative embodiment, a channel plate 210 may act as the wall of the heat exchanger 202 and serve to thermally couple the dry and wet channels 204, 206 together. In other embodiments, the channels 204, 206 are set in alternative arrangements that permit heat transfer between the channels.

In an alternative embodiment, the heat exchanger comprises a single dry channel 204 and wet channel 206.

In the embodiment shown in FIG. 3, TEGs 216 are located on and form the dry channel walls. The surface of the dry channel walls are depicted as 204a, 204b.

Each channel 204, 206 forms an enclosed space passing from a respective fluid inlet 218, 220 to a fluid outlet 222, 224. Fluid flows from each inlet through the respective channel, to the outlet. The walls 206a, 206b of the wet channel are coated in a liquid 208. In the embodiment shown, the walls 206a, 206b are coated in water 108. As the second heat transferring fluid 214 passes through the wet channel 206, water from the walls 206a, 206b evaporates, thereby reducing the temperature of the walls 206a, 206b. As the walls of the wet channel 206 cool, heat is transferred from the dry channel 204 to the wet channel 206. The first heat transferring fluid 212 passing through the dry channel 204 is thereby cooled through contact with the surface of the dry channel walls 204a, 204b. The heat flux passes through the plates 210 and consequently through the TEG and/or TEGs 216 and the heat flux is converted to electrical energy.

In the embodiment shown in FIG. 3, the TEGs 216 are located on the dry side of every channel wall 204a, 204b of the heat exchanger 202 and extend the length of the entirety of the channel wall 204a, 204b. In an alternative embodiment, the TEGs are located on the dry side of at least one channel wall 204, 204b and extends the length of at least a portion of the channel wall.

In the embodiment shown in FIG. 3, the heat exchanger 202, the plates/walls 210, and TEGs 216 are comprised of a non-woven fabric, such as a Polyethylene Terephthalate (PET) non-woven fabric. In other embodiments, the plates/walls 210 and TEGs 216 are comprised of materials suitable for heat exchange which include but are not limited to metals and metal alloys, such as aluminum, copper, carbon steel, stainless steel, nickel alloys, and titanium. In another embodiment, the plates/walls 210 and TEGs 216 are comprised of ceramic material.

Although the foregoing discussion refers to the dry channel 204 and wet channel 206 as having “walls” 204a, 204b, 206a, 206b, it will be understood that any three-dimensional arrangement could be used. In an embodiment, the channels 204, 206 each comprise a cylinder. Substantially all of the walling of the wet channel 206 may be coated in water. Alternatively, the channels 204, 206 may comprise rectangular prisms. In such embodiment, only the “floor” of the wet channel 206 may be coated in water 208. As will be clear to one of skill in the art, the cooling capacity of the system 200 may be selected by adjusting the number of channels 204, 206 and/or the area of contact between the walls of the channels 204, 206 and the fluid 212, 214 passing through the channels 204, 206. Greater contact area will increase the amount of evaporation and/or condensation, thereby enabling both the degree of pre-cooling and the amount of dehumidification to be adjusted based on the desired capacity of the system 200.

In the embodiment shown in FIG. 3, the heat transfer process is continuous, allowing the TEGs 216 to continuously generate electrical energy and enhance the performance of the unit. The collected electrical energy can be used to power the supplementary equipment required by the heat exchanger 202 (e.g., pumps or fans), or it can be used for other applications.

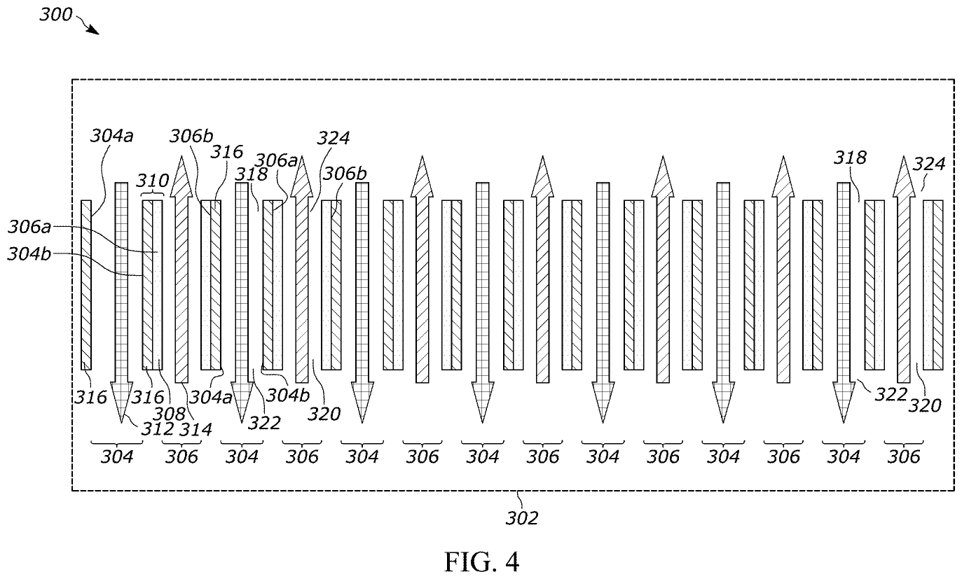

FIG. 4 shows a heat exchanger 302 wherein TEGs 316 comprise the channel walls 304a, 304b, 306a, 306b and corresponding plates 310. In the embodiment of FIG. 3, similarly labeled elements are incorporated into this embodiment (i.e., elements 102, 202, 302 all represent the heat exchanger).

FIG. 4 shows the heat exchanger 302 comprising an alternating series of dry channels 304 and wet channels 306 thermally coupled together. In an alternative embodiment, each dry channel 304 is thermally coupled to a single wet channel 306. In alternative embodiments, multiple dry channels 304 are thermally coupled to one or more wet channels 306. As shown in the embodiment of FIG. 4, TEGs 316 form at least a portion of the walls of both the wet and dry channels 304, 306. In a further embodiment, the TEGs 316 form the entire wall of the wet and dry channels 304, 306.

In an embodiment, either a wet or dry channel wall may for the end of the heat exchanger 302. In alternative embodiments, TEG(s) 316 comprise at least a portion of the channel plates 310 which may also act as a wall of the heat exchanger 310 and serve to thermally couple the dry and wet channels 304, 306 together. In other embodiments, the channels 304, 306 are set in alternative arrangements that permit heat transfer between the channels.

In an alternative embodiment, the heat exchanger comprises a single dry channel 304 and a wet channel 306.

In the embodiment shown in FIG. 4, the wet and dry channel walls 304a, 304b, 306a, 306b are comprised of TEGs 316.

Each channel 304, 306 forms an enclosed space passing from a respective fluid inlet 318, 320 to a fluid outlet 322, 324. Fluid flows from each inlet through the respective channel, to the outlet. The walls 306a, 306b of the wet channel are coated in a liquid 208. In the embodiment shown, the walls 306a, 306b are coated in water 308. As the second heat transferring fluid 314 passes through the wet channel 306, water from the walls 306a, 306b evaporates, thereby reducing the temperature of the walls 306a, 306b. As the walls of the wet channel 306 cool, heat is transferred from the dry channel 304 to the wet channel 306. The first heat transferring fluid 312 passing through the dry channel 304 is thereby cooled through contact with the surface of the dry channel walls 304a, 304b. The heat flux passes through the heat exchanger 302 plates 310 and consequently through the TEG and/or TEGs 316 and the heat flux is converted to electrical energy.

In the embodiment shown in FIG. 4, the heat exchanger 302, and the wet and dry channel walls 304a, 204b, 306a, 306b (i.e., TEGs 316) are comprised of a non-woven fabric, such as a Polyethylene Terephthalate (PET) non-woven fabric. In other embodiments, TEGs 316 are comprised of materials suitable for heat exchange which include but are not limited to metals and metal alloys, such as aluminum, copper, carbon steel, stainless steel, nickel alloys, and titanium. In another embodiment, the TEGs 316 are comprised of ceramic material.

Although the foregoing discussion refers to the dry channel 304 and wet channel 306 as having “walls” 304a, 304b, 306a, 306b, it will be understood that any three-dimensional arrangement could be used. In an embodiment, the channels 304, 306 each comprise a cylinder. Substantially all of the walling of the wet channel 306 may be coated in water. Alternatively, the channels 304, 306 may comprise rectangular prisms. In such embodiment, only the “floor” of the wet channel 306 may be coated in water 308. As will be clear to one of skill in the art, the cooling capacity of the system 300 may be selected by adjusting the number of channels 304, 306 and/or the area of contact between the walls of the channels 304, 306 and the fluid 312, 314 passing through the channels 304, 306. Greater contact area will increase the amount of evaporation and/or condensation, thereby enabling both the degree of pre-cooling and the amount of dehumidification to be adjusted based on the desired capacity of the system 300.

In the embodiment shown in FIG. 4, the heat transfer process is continuous, allowing the TEGs 316 to continuously generate electrical energy and enhance the performance of the unit. The collected electrical energy can be used to power the supplementary equipment required by the heat exchanger 302 (e.g., pumps or fans), or it can be used for other applications.

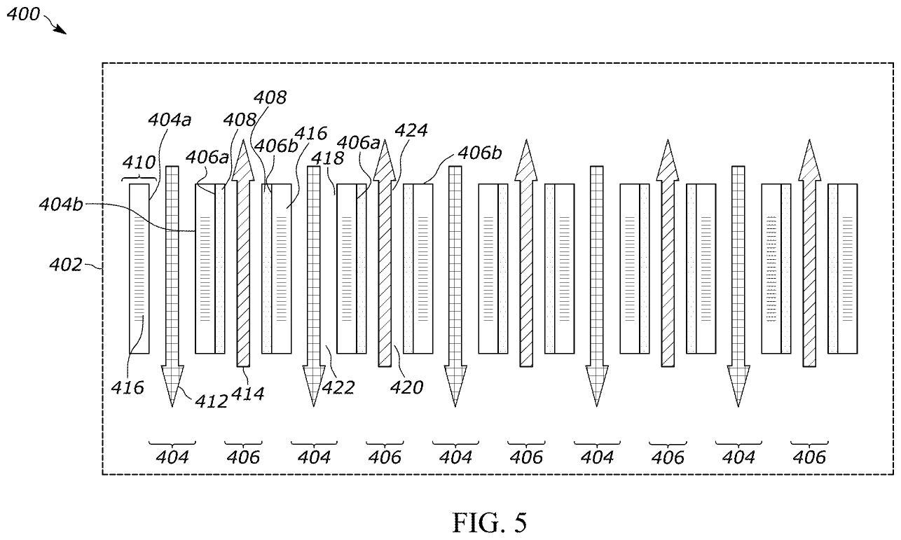

FIG. 5 shows a heat exchanger wherein TEGs 416 are embedded into the channel walls 404a, 404b, 406a, 406b. In the embodiment of FIG. 4, similarly labeled elements are incorporated into this embodiment (i.e., elements 102, 202, 302, and 402) all represent the heat exchanger 402.

FIG. 5 shows the heat exchanger 402 comprising an alternative series of dry channels 404 and wet channels 404 thermally coupled together. In embodiments, each dry channel 404 is thermally coupled to a single wet channel 406. In alternative embodiments, multiple dry channels 404 are thermally coupled to one or more wet channels 406.

As shown in the embodiment of FIG. 5, TEGs 416 are incorporated within the walls of the wet and dry channels 404a, 404b, 406a, 406b. The channel walls and TEGs 416 form the channel plate 410, which may act as a wall of the heat exchanger 402 and serve to thermally couple the dry and wet channels 404, 406 together. In other embodiments, the channels 404, 406 are set in alternative arrangements that permit heat transfer between the channels.

In an alternative embodiment, the heat exchanger 402 comprises a single dry channel 404 and a wet channel 406.

In the embodiment shown in FIG. 5, TEGs 416 are embedded into channel walls 404a, 404b, 406a, 406b. Each channel 404, 406 forms an enclosed space passing from a respective fluid inlet 418, 420 to a fluid outlet 422, 424. Fluid flows from each inlet through the respective channel, to the outlet. The walls 406a, 406b of the wet channel are coated in a liquid 408. In the embodiment shown, the walls 406a, 406b are coated in water 408. As the second heat transferring fluid 414 passes through the wet channel 406, water from the walls 406a, 406b evaporates, thereby reducing the temperature of the walls 406a, 406b. As the walls of the wet channel 406 cool, heat is transferred from the dry channel 404 to the wet channel 406. The first heat transferring fluid 412 passing through the dry channel 404 is thereby cooled through contact with the surface of the dry channel walls 404a, 404b.

The heat flux passes through the heat exchanger walls 410 and consequently through the TEG and/or TEGs 416 and the heat flux is converted to electrical energy.

In the embodiment shown in FIG. 5, the TEGs are embedded within every channel wall 404a, 404b, 406a, 406b of the heat exchanger 402 and extend the length of the entirety of the channel wall. In an alternative embodiment, the TEGs 416 are embedded within at least one channel wall and extend the length of at least a portion of the channel wall.

In the embodiment shown in FIG. 5, the heat exchanger 402, the plates/walls 410, and TEGs 416 are comprised of a non-woven fabric, such as a Polyethylene Terephthalate (PET) non-woven fabric. In other embodiments, the plates/walls 410, and TEGs 416 are comprised of materials suitable for heat exchange which include but are not limited to metals and metal alloys, such as aluminum, copper, carbon steel, stainless steel, nickel alloys, and titanium. In another embodiment, the plates/walls 410 and TEGs 416 are comprised of ceramic material.

Although the foregoing discussion refers to the dry channel 404 and wet channel 406 as having “walls” 404a, 404b, 406a, 406b, it will be understood that any three-dimensional arrangement could be used. In an embodiment, the channels 404, 406 each comprise a cylinder. Substantially all of the walling of the wet channel 406 may be coated in water. Alternatively, the channels 404, 406 may comprise rectangular prisms. In such embodiment, only the “floor” of the wet channel 406 may be coated in water 408. As will be clear to one of skill in the art, the cooling capacity of the system 400 may be selected by adjusting the number of channels 404, 406 and/or the area of contact between the walls of the channels 404, 406 and the fluid 412, 414 passing through the channels 404, 406. Greater contact area will increase the amount of evaporation and/or condensation, thereby enabling both the degree of pre-cooling and the amount of dehumidification to be adjusted based on the desired capacity of the system 400.

In the embodiment shown in FIG. 5, the heat transfer process is continuous, allowing the TEGs 416 to continuously generate electrical energy and enhance the performance of the unit. The collected electrical energy can be used to power the supplementary equipment required by the heat exchanger 402 (e.g., pumps or fans), or it can be used for other applications.

In the present disclosure, the heat exchanger 102, 202, 302, 402, acts passively on the exhaust and outside air. No energy is required for the cooling and dehumidification that occurs during the heat exchange process. In alternative embodiments, active cooling and dehumidification may also occur in the heat exchanger in addition to the passive cooling and dehumidification discussed above, thereby improving on the efficiency of traditional active cooling systems while still ensure the desired degree of cooling is consistently provided.

Having thus described in detail preferred embodiments of the present disclosure, it is to be understood that the disclosure defined by the above paragraphs is not to be limited to particular details set forth in the above description as many apparent variations thereof are possible without departing from the spirit or scope of the present disclosure.

1. A heat exchanger comprising:
a first channel, the first channel comprising:
a first inlet proximate a first end of the first channel, the first inlet configured to intake a first heat transferring fluid;
and a first outlet proximate a second end of the first channel, the first outlet configured to expel the first heat transferring fluid;
a second channel, the second channel comprising:
a second inlet proximate a first end of the second channel, the second inlet configured to intake a second heat transferring fluid;
and a second outlet proximate a second end of the second channel, the second outlet configured to expel the second heat transferring fluid; and
wherein a thermoelectric generator (TEG) is incorporated between the wall of the first channel and adjacent wall of the second channel to form a shared, thermally coupled wall.

2. The heat exchanger of claim 1, wherein the first channel comprises a dry channel and a liquid is disposed along the walls of the second channel to form a wet channel.

3. The heat exchanger of claim 2, wherein the second heat transferring fluid interacts with the liquid to reduce the temperature on the second channel side of the shared thermally coupled wall and the first channel transfers heat through the thermally coupled wall (and TEG) to the second channel, wherein the resulting heat flux is converted to energy.

4. The heat exchanger of claim 3, wherein the heat exchanger further comprises additional dry and wet channels arranged in an alternating pattern wherein a TEG is incorporated between the walls of the wet and dry channels which form shared, thermally coupled walls.

5. The heat exchanger of claim 4, wherein the channels of the heat exchanger are comprised of rectangular prisms.

6. The heat exchanger of claim 4, wherein the channels of the heat exchanger are comprised of cylinders.

7. The heat exchanger of claim 4, wherein the channels of the heat exchanger are comprised of polyethylene non-woven fabric, metal, metal alloy, ceramic material or a combination thereof.

8. A heat exchanger comprising an alternating series of wet and dry channels and a plurality of thermoelectric generators (TEGs), wherein the adjacent walls of the wet and dry channels form shared, thermally coupled walls and the TEGs are located proximate the thermally coupled walls.

9. The heat exchanger of claim 8 wherein:
each of the dry channels comprise:
a first inlet proximate a first end of the first channel, the first inlet configured to intake a first heat transferring fluid; and
a first outlet proximate a second end of the first channel, the first outlet configured to expel the first heat transferring fluid; and
each of the wet channels comprise:
liquid disposed within the wet channel;
a second inlet proximate a first end of the second channel, the second inlet configured to intake a second heat transferring fluid; and
a second outlet proximate a second end of the second channel, the second outlet configured to expel the second heat transferring fluid; and
wherein the second heat transferring fluid interacts with the liquid to reduce the temperature on the wet channel side of the shared thermally coupled wall and the dry channel transfers heat through the thermally coupled wall (and TEG) to the wet channel, wherein the resulting heat flux is converted to energy.

10. The heat exchanger of claim 9, wherein the channels of the heat exchanger are comprised of rectangular prisms.

11. The heat exchanger of claim 9, wherein the channels of the heat exchanger are comprised of cylinders.

12. The heat exchanger of claim 9, wherein the channels of the heat exchanger are comprised of polyethylene non-woven fabric, metal, metal alloy, ceramic material or a combination thereof.

13. The heat exchanger of claim 9, wherein the TEGs are embedded into the thermally coupled walls.

14. The heat exchanger of claim 9, wherein the TEGs form the entirety of the thermally coupled walls.

15. The heat exchanger of claim 9, wherein the TEGs form the dry channel walls and together with the adjacent wall of the wet channels form shared, thermally coupled walls.

16. The heat exchanger of claim 9, wherein the TEGs connect to an electrical wire which transfers energy from the TEGs to additional heat exchange components.

17. The heat exchanger of claim 16, wherein the additional heat exchange components comprise supply fans to improve the movement of the first and second heat transferring fluids through the wet and dry channels or pumps to deliver the liquid to the wet channel for evaporation.

18. A method of generating electricity to improve heat exchanger efficiency, the method comprising the steps of:
drawing a first heat transfer fluid through the inlets of a plurality of dry channels and discharging the heat transfer fluid through the outlets of the dry channels;
drawing a second heat transfer fluid through the inlets of a plurality of wet channels and discharging the second heat transfer fluid through the outlets of the wet channels, wherein:
the walling of the adjacent wet channel and dry channel walls comprise a shared thermally coupled wall;
a thermoelectric generator (TEG) is located proximate the thermally coupled walls; and
the passage of the second heat transfer fluid through the wet channels evaporates liquid within the wet channels to cool the wet channels and the dry channels transfer heat to the wet channels and generate energy as the heat flux passes through the TEG.

19. The method of claim 18, wherein the TEGs connect to an electrical wire to transfer energy from the TEGs to additional heat exchange components.

20. The method of claim 19, wherein the additional heat exchange components comprise supply fans to improve the movement of the first and second heat transferring fluids through the wet and dry channels or pumps to deliver the liquid to the wet channel for evaporation.
